(19) United States
(12) Patent Application Publication
(10) Pub. No.: US 2011/0045668 A1
(43) Pub. Date: Feb. 24, 2011

(54) Method of manufacturing wafer level device package

(75) Inventors: Hyung Jin Jeon, Gunpo (KR); Young Do Kweon, Seoul (KR); Seung Wook Park, Suwon (KR); Jong Yun Lee, Incheon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/654,373

(22) Filed: Dec. 17, 2009

(30) Foreign Application Priority Data
Aug. 18, 2009 (KR) 10-2009-0076190

(51) Int. Cl. H01L 21/768

(52) U.S. Cl. 438/627; 257/E21.584; 257/E21.575

(57) ABSTRACT

There is provided a method of manufacturing a wafer level device package, the method including: forming a conductive pad on at least one area of a substrate; forming a first insulation layer on the substrate, the first insulation layer having an opening allowing the conductive pad to be exposed; forming a wiring layer connected to the conductive pad on the first insulation layer; forming a conductive diffusion barrier layer on the wiring layer to seal the wiring layer; forming a second insulation layer on the diffusion barrier layer, the second insulation layer having a contact hole allowing a part of diffusion barrier layer to be exposed; and forming a bump pad in the contact hole. This method allows for a reduction in processing time and costs by substituting a simple electroless plating process for a complicated photolithography process in the formation of the bump pad and the diffusion barrier layer.

### CROSS-REFERENCE TO RELATED APPLICATIONS

This application claims the priority of Korean Patent Application No. 10-2009-0076190 filed on Aug. 18, 2009, in the Korean Intellectual Property Office, the disclosure of which is incorporated herein by reference.

### BACKGROUND OF THE INVENTION

1. Field of the Invention

The present invention relates to a method of manufacturing a wafer level device package, and more particularly, to a method of manufacturing a wafer level device package allowing for a reduction in processing time and manufacturing costs by substituting a simple electroless plating process for a complicated photolithography process in the formation of a bump pad.

2. Description of the Related Art

Recently, as semiconductor devices have shrunk in size, growing attention has been drawn to packaging technology. A wafer level package technology refers to a semiconductor packaging technology that packages chips at a wafer level where the chips are not cut or separated, as opposed to an existing technology that cuts a wafer into individual chips and packages them.

Specifically, a single semiconductor package is fabricated through four operations: circuit design, wafer processing, assembly, and inspection. The assembly process includes a wire bonding process and a packaging process. The assembly process includes cutting a process-finished wafer into individual chips, attaching the individual chips to a small circuit board, bonding wires, and sealing the chips with a plastic package.

The wafer level packaging is accomplished by a simple procedure. That is, instead of plastic, which has previously been used as a package material, individual chips disposed on the wafer are coated with a photosensitive insulation material. After wires are bonded thereto, an insulation material is coated thereupon.

Such a wafer level package technology can simplify manufacturing procedures, and thereby reduce the time required for the semiconductor assembly process. Furthermore, manufacturing costs can be markedly reduced because the plastic, the circuit board, and the wires, which have been used for the semiconductor assembly, are not needed. In particular, since the wafer level package technology allows for the fabrication of a package having the same size as the chip, the package size can be reduced by approximately 20% or more when compared with a typical chip scale package (CSP) that has been applied to the shrinkage of the semiconductor package.

In this wafer level package technology, copper has been commonly used in a wiring layer. In this case, there is an advantage in the enhancement of electrical characteristics; however, it is difficult to prevent current diffusion in copper.

Also, photolithography, including complicated processes and large incurred costs, is required to form a bump pad on an insulation layer for the electrical connection with another device.

### SUMMARY OF THE INVENTION

An aspect of the present invention provides a method of manufacturing a wafer level device package allowing for a reduction in processing time and manufacturing costs by substituting a simple electroless plating process for a complicated photolithography process in the formation of a bump pad and a diffusion barrier layer.

According to an aspect of the present invention, there is provided a method of manufacturing a wafer level device package, the method including: forming a conductive pad on at least one area of a substrate; forming a first insulation layer on the substrate, the first insulation layer having an opening allowing the conductive pad to be exposed; forming a wiring layer connected to the conductive pad on the first insulation layer; forming a conductive diffusion barrier layer on the wiring layer to seal the wiring layer; forming a second insulation layer on the diffusion barrier layer, the second insulation layer having a contact hole allowing a part of diffusion barrier layer to be exposed; and forming a bump pad in the contact hole.

The wiring layer may be formed of copper.

The wiring layer may be configured as a redistribution layer.

The diffusion barrier layer may be formed by electroless plating.

The diffusion barrier layer may be formed of nickel.

The bump pad may be formed by electroless plating.

The bump pad may be configured as at least a double layer of a secondary diffusion barrier layer and an antioxidant layer.

The bump pad may be configured as a double layer of nickel and gold.

The forming of the conductive pad may further include forming a groove portion by etching the substrate and forming the conductive pad in the groove portion.

The bump pad may be formed by electroless plating.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a schematic cross-sectional view illustrating the formation of a first insulation layer on a substrate having a conductive pad formed thereon according to an exemplary embodiment of the present invention;

FIG. 1B is a plan view of FIG. 1A;

FIG. 2A is a schematic cross-sectional view illustrating the formation of a first insulation layer while allowing a conductive pad to be exposed according to an exemplary embodiment of the present invention;

FIG. 2B is a plan view of FIG. 2A;

FIG. 3A is a schematic cross-sectional view illustrating the formation of a wiring layer in contact with a conductive pad on the first insulation layer according to an exemplary embodiment of the present invention;

FIG. 3B is a plan view of FIG. 3A;

FIG. 4A is a schematic cross-sectional view illustrating the formation of a diffusion barrier layer on a wiring layer to seal the wiring layer according to an exemplary embodiment of the present invention;

FIG. 4B is a plan view of FIG. 4A;

FIG. 5A is a schematic cross-sectional view illustrating the formation of a second insulation layer having a contact hole allowing a part of diffusion barrier layer to be exposed according to an exemplary embodiment of the present invention;

FIG. 5B is a plan view of FIG. 5A;

FIG. 6A is a schematic cross-sectional view illustrating the formation of a bump pad in a contact hole according to an exemplary embodiment of the present invention; and

FIG. 6B is a plan view of FIG. 6A.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

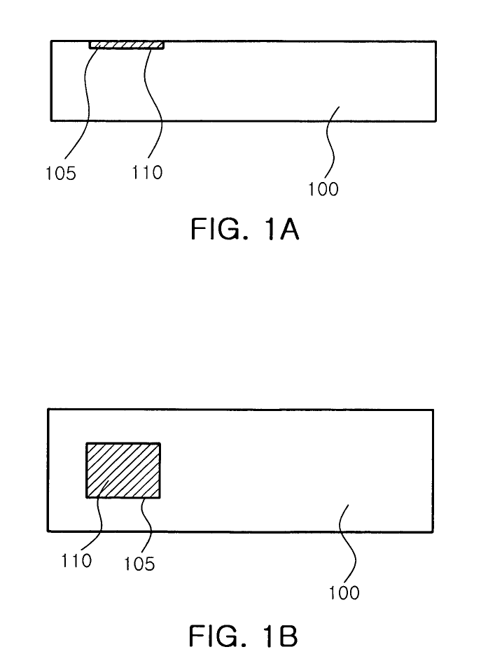

FIGS. 1A through 6B are schematic cross-sectional views or top views illustrating a manufacturing process of a semiconductor device 1 according to an exemplary embodiment of the present invention.

First of all, as shown in FIGS. 1A and 1B, a prepared semiconductor substrate 100 is etched to form a groove portion 105 and a conductive pad 110 is formed in the groove portion 105. Here, the groove portion 105 may be formed by photolithography.

The substrate 100 may have a photosensitive resin layer (not shown) coated thereon. The coated photosensitive resin layer may be subject to exposure and development using a mask (not shown) having a predetermined pattern to thereby form the groove portion 105.

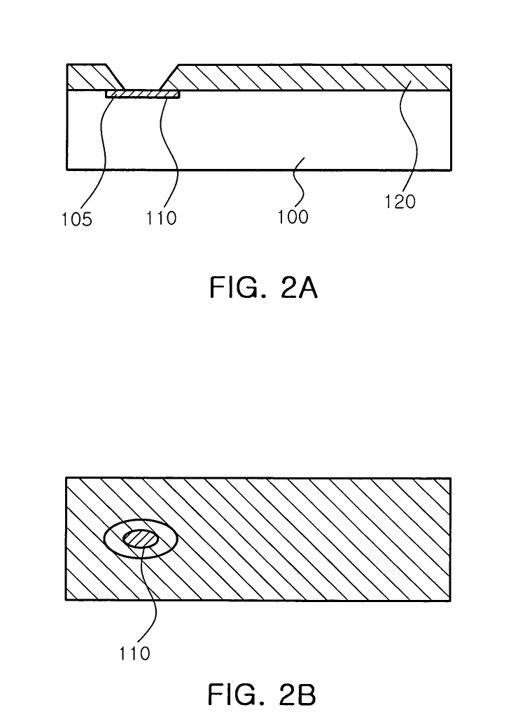

Next, as shown in FIGS. 2A and 2B, a first insulation layer 120 is formed on the substrate 100 in such a manner that the conductive pad 110 is allowed to be exposed. Here, the first insulation layer 120 may be formed by coating the substrate 100 with a photosensitive resin layer (not shown) and performing the exposure and development of the coated photosensitive resin layer using a mask (not shown) having a predetermined pattern.

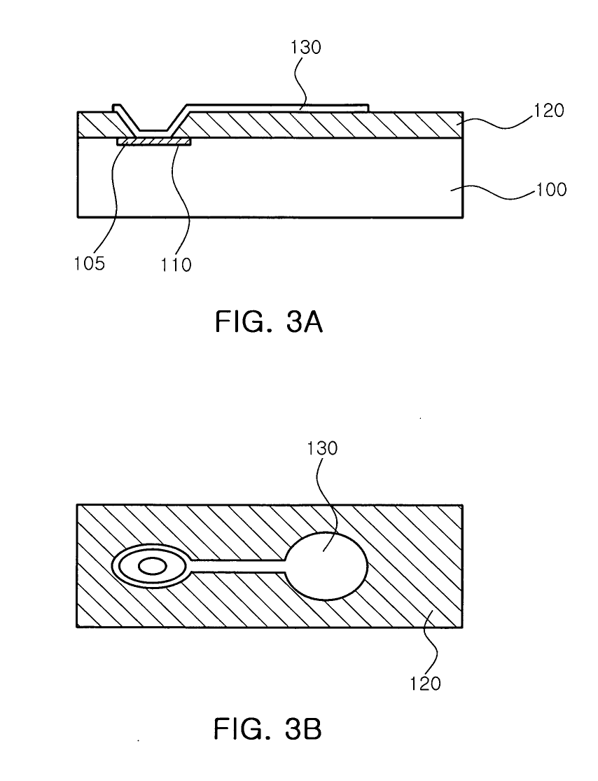

After that, as shown in FIGS. 3A and 3B, a wiring layer 130 in electrical connection with the conductive pad 110 may be formed on the first insulation layer 120. Here, the wiring layer 130 may be formed of copper and be formed by coating a photosensitive resin layer (not shown) on the first insulation layer 120 and performing the exposure and development of the coated photosensitive resin layer using a mask (not shown) having a predetermined pattern.

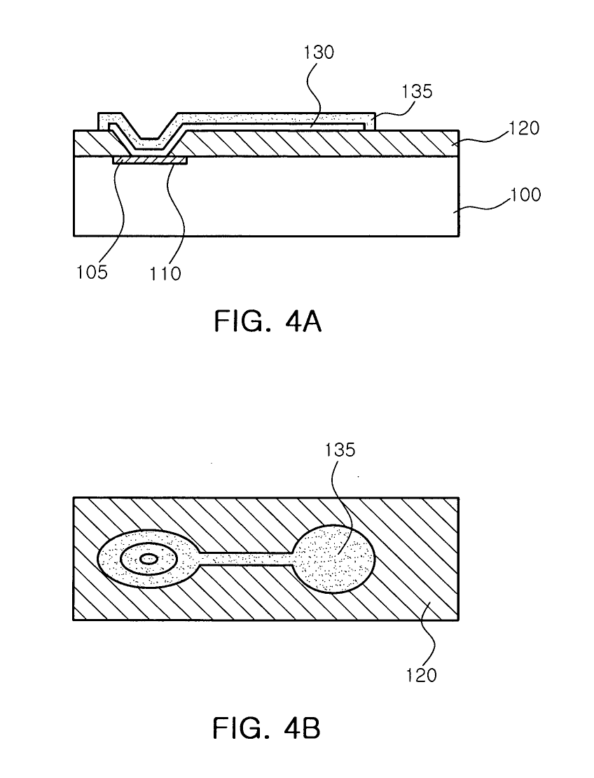

Then, as shown in FIGS. 4A and 4B, a conductive diffusion barrier layer 135 is formed on the wiring layer 130 to thereby seal the wiring layer 130. Here, the conductive diffusion barrier layer 135 may be formed of nickel and be formed by electroless plating.

Copper may be good for wires due to properties of low electrical resistance, but it also has low electromigration resistance. Also, when copper wires are densely packed close to each other, an insulation failure may occur. The conductive diffusion barrier layer 135 formed of nickel in the present embodiment may be formed to seal the wiring layer 130 formed of copper, thereby preventing the copper wiring layer 130 from being exposed to the outside. Also, the electromigration resistance of the copper wiring layer 130 may be improved. Here, the wiring layer 130 may be configured as a redistribution layer.

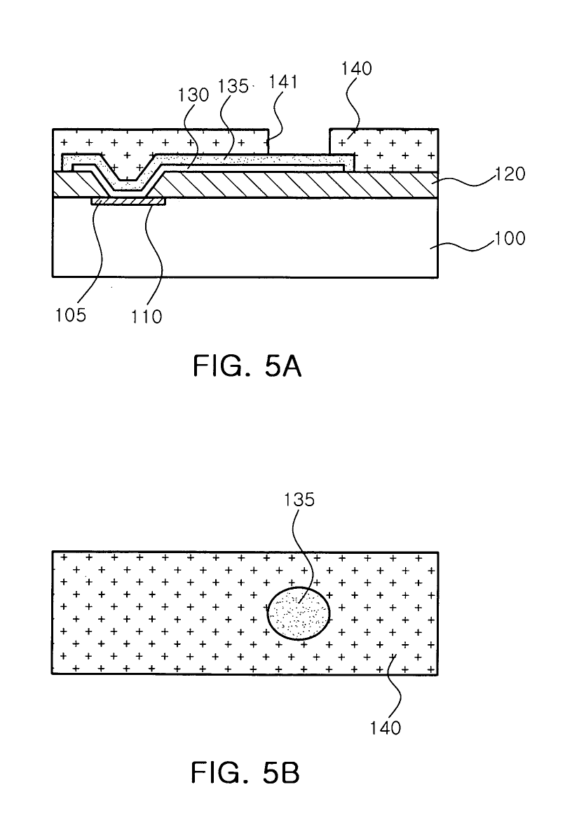

Then, as shown in FIGS. 5A and 5B, a second insulation layer 140 is formed on the conductive diffusion barrier layer 135 in such a manner that it has a contact hole 141 allowing a part of the conductive diffusion barrier layer 135 to be exposed.

Here, the second insulation layer 140 may be formed by coating an insulation material (not shown) and a photosensitive resin layer (not shown) on the conductive diffusion barrier layer 135 and performing the exposure and development of the photosensitive resin layer using a mask (not shown) having a predetermined pattern.

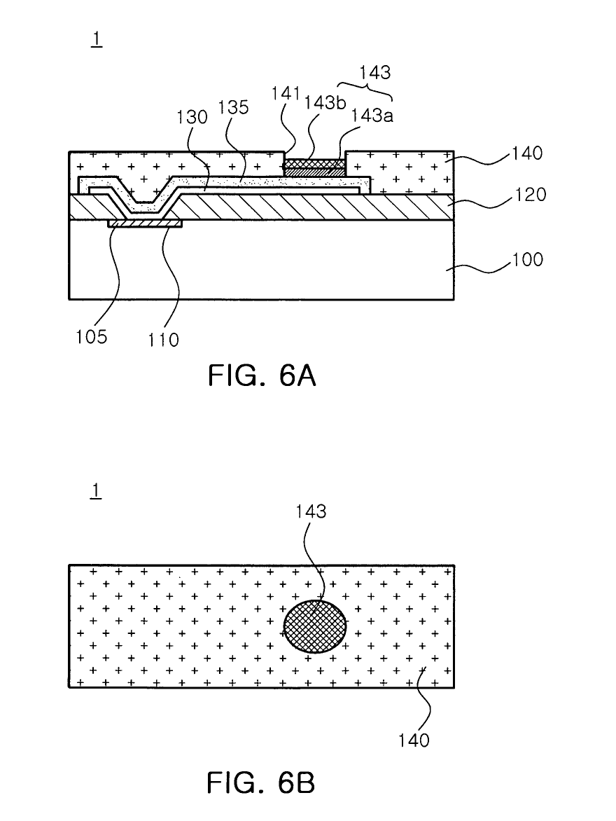

Finally, as shown in FIGS. 6A and 6B, a bump pad 143 is formed in the contact hole 141 formed in the second insulation layer 140. Here, the bump pad 143 may include a first bump pad layer 143a and a second bump pad layer 143b. The first bump pad layer 143a may be formed of nickel and the second bump pad layer 143b may be formed of gold. Here, the first bump pad layer 143a formed of nickel may act as a secondary copper-diffusion barrier layer, and the second bump pad layer 143b formed of gold may act as an antioxidant film. The bump pad 143 may be formed by electroless plating.

As described above, the semiconductor device 1 may be connected to components such as a bump (not shown) through the bump pad 143 formed in the contact hole 141.

According to an exemplary embodiment of the invention, the substrate 100, divided into a plurality of areas, is cut to form individual device packages. When a bump pad is formed by an existing depositing method or electroplating method, respective processes are performed in the unit of individual devices, resulting in inefficiency. However, when a diffusion barrier layer and a bump pad are formed by electroless plating according to the present embodiment, there is an advantage in processing efficiency by cutting a desired number of individual devices after being formed on the substrate.

Also, processing time and costs may be reduced by substituting a simple electroless plating process for a complicated photolithography process for the formation of a bump pad.

As set forth above, according to exemplary embodiments of the invention, there is provided a method of manufacturing a wafer level device package allowing for a reduction in processing time and costs by substituting a simple electroless plating process for a complicated photolithography process for the formation of a bump pad.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a wafer level device package, the method comprising:
forming a conductive pad on at least one area of a substrate;
forming a first insulation layer on the substrate, the first insulation layer having an opening allowing the conductive pad to be exposed;
forming a wiring layer connected to the conductive pad on the first insulation layer;
forming a conductive diffusion barrier layer on the wiring layer to seal the wiring layer;
forming a second insulation layer on the diffusion barrier layer, the second insulation layer having a contact hole allowing a part of diffusion barrier layer to be exposed; and
forming a bump pad in the contact hole.

2. The method of claim 1, wherein the wiring layer is formed of copper.

3. The method of claim 1, wherein the wiring layer is configured as a redistribution layer.

4. The method of claim 1, wherein the diffusion barrier layer is formed by electroless plating.

5. The method of claim 1, wherein the diffusion barrier layer is formed of nickel.

6. The method of claim 3, wherein the bump pad is formed by electroless plating.

7. The method of claim 1, wherein the bump pad is configured as at least a double layer of a secondary diffusion barrier layer and an antioxidant layer.

8. The method of claim 7, wherein the bump pad is configured as a double layer of nickel and gold.

9. The method of claim 1, wherein the forming of the conductive pad comprises:
forming a groove portion by etching the substrate; and
forming the conductive pad in the groove portion.

10. The method of claim 1, wherein the bump pad is formed by electroless plating.
